(19) United States
(12) Patent Application Publication
(10) Pub. No.: US 2026/0296239 A1
(43) Pub. Date: Oct. 1, 2026

(54) MOUNT FOR POWER CONVERSION MODULE

(71) Applicant: TRITIUM POWER SOLUTIONS PTY LTD, Narre Warren South (AU)

(72) Inventors: Lyndon James Arden PHIPPS, Narre Warren South (AU); Nathan David VAN DER HEIDE, Narre Warren South (AU); Benjamin David GUYMER, Narre Warren South (AU); Calem Timothy WALSH, Narre Warren South (AU)

(21) Appl. No.: 19/479,631

(22) PCT Filed: Apr. 29, 2024
(86) PCT No.: PCT/AU2024/050413

§ 371 Date: Oct. 28, 2025

(30) Foreign Application Priority Data
Apr. 28, 2023 (AU) 2023901260

(51) Int. Cl. B60L 53/31; H01R 12/70; H05K 7/14

(52) U.S. Cl. CPC B60L 53/31; H01R 12/7076; H01R 12/7088; H05K 7/1417; H05K 7/14325; H05K 7/14329; B60L 2210/10; B60L 2210/30

(57) ABSTRACT

A mount for a power conversion module for charging an electric vehicle. The mount includes a front side to face the power conversion module and a back side to face a circuit board assembly comprising a data connector. The mount also includes an alignment surface accessible from the front side to receive a corresponding alignment feature of the power conversion module and configured to align the power conversion module with the mount for connection of the power conversion module to the data connector. There is also a protrusion extending from the back side to mate with a corresponding alignment formation provided by the circuit board assembly to align the mount to the circuit board assembly.

### CROSS REFERENCE TO RELATED APPLICATIONS

The present application is a U.S. National Phase of International Application No. PCT/AU2024/050413 entitled “MOUNT FOR POWER CONVERSION MODULE,” and filed on Apr. 29, 2024. International Application No. PCT/AU2024/050413 claims priority to Australian Patent Application No. 2023901260 filed on Apr. 28, 2023. The entire contents of each of the above-listed applications are hereby incorporated by reference for all purposes.

### TECHNICAL FIELD

This disclosure relates to a mount for a power conversion module.

### BACKGROUND

Power conversion modules are used in a range of different applications, including in electric vehicle (EV) chargers. Such power conversion modules comprise a data connector for data communication between the power conversion module and control electronics, such as the charging controller of the EV. The power electronics control the flow of electric power to the EV as demanded by the charging controller of the EV. Further, such power conversion modules comprise power connectors as power input and power output.

The power conversion modules are installed in a cabinet to form an EV charging station. While such a modular design provides flexibility in building EV charging stations, the mounting of the modules is difficult. In particular, the modules are densely packed with power electronics and therefore relatively heavy. As a result, a relatively large force is used to lift them and move them into place. However, they also need to be moved into a mating position with the data connector, which is a relatively subtle operation with tight tolerances and fragile equipment. So there is a need for a mount for a power conversion module that facilitates the mating with the data connector for such heavy modules.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of the subject matter disclosed herein.

### SUMMARY

This disclosure relates to a mount for a power conversion module for charging an electric vehicle, the mount comprising:
a front side to face the power conversion module;
a back side to face a circuit board assembly comprising a data connector;
an alignment surface accessible from the front side to receive a corresponding alignment feature of the power conversion module and configured to align the power conversion module with the mount for connection of the power conversion module to the data connector;
a protrusion extending from the back side to mate with a corresponding alignment formation provided by the circuit board assembly to align the mount to the circuit board assembly.

It is an advantage that the mount provides both alignment with the power conversion module as well as the circuit board assembly. This way the chain of tolerances is short and accurate alignment between the power conversion module and the circuit board assembly can be achieved even if the mount itself is not manufactured to low tolerances throughout. That is, it is only the spatial relationship between the alignment surface and the protrusion that defines the tolerance. As a result, the mount can be mass-produced using more cost efficient manufacturing techniques compared to high precision machining, which is slow and produces a significant amount of material waste.

In some embodiments, the protrusion is proximal to the alignment surface.

In some embodiments, the mount is integrally formed with the alignment surface and the protrusion.

In some embodiments, the alignment surface is proximal to the data connector.

In some embodiments, the alignment surface is inside of an opening through the mount, the opening being in a direction of movement of the power conversion module when mating the power conversion module with the data connector.

In some embodiments, the data connector of the circuit board assembly is located within the opening.

In some embodiments, the alignment surface is chamfered inwardly from the front side to guide the alignment feature into a mating position with the alignment surface.

In some embodiments, the mount defines a chain of tolerances from the alignment surface of the power conversion module to the data connector of the circuit board assembly via the alignment feature and the alignment surface and via the protrusion and the circuit board assembly.

In some embodiments, the tolerance of the alignment surface is less than 150 μm and the tolerance of the protrusion is less than 100 μm.

In some embodiments, the circuit board assembly comprises a printed circuit board and the alignment formation is an aperture through the printed circuit board.

In some embodiments, the protrusion is a boss around a screw hole to clamp the mount against the circuit board assembly.

In some embodiments, the mount comprises a slot distal from the alignment surface to receive a corresponding foot of the power conversion module to provide rotational alignment to the power conversion module.

In some embodiments, the mount comprises a load transfer feature to transfer mechanical load from the power conversion module to a back plate, the load transfer feature being directly below the slot.

In some embodiments, the mount comprises an input channel for housing a vertical input busbar and an output channel for housing a vertical output busbar.

In some embodiments, the mount comprises openings over the input channel and the output channel to receive clips of the power conversion module, the clips being configured to slidably engage with the input busbar and the output busbar.

In some embodiments, the mount comprises a rear component to clamp the circuit board assembly, the input busbar and the output busbar to the back side.

In some embodiments, the rear component comprises a screw post for receiving a screw fed through the protrusion of the mount and the hole in the circuit board assembly.

A backplane assembly for multiple power conversion modules comprises:
one or more first mounts as described herein, the first mounts being configured to mount respective AC to DC rectifiers located at the bottom of the backplane assembly;
one or more second mounts as described herein, the second mounts being configured to mount respective DC to DC converters located at the top of the backplane assembly;
an AC busbar connecting the rectifiers to an input AC power source, the AC busbar running through the input channel of the first mounts;
a first DC busbar connecting an output of the rectifiers to an input of the converters, the first DC busbar running through the output channel of the first mounts and through the input channel of the second mounts;
a second DC busbar connecting an output of the converters to an output assembly comprising a charging cable, the second DC busbar running through the output channel of the second mounts,
wherein the input channel of the first mounts is vertically aligned with and insulated from the output channel of the second mounts.

A method for installing a power conversion module in a housing for charging an electric vehicle comprises:
placing a circuit board assembly in the housing, the circuit board assembly comprising a data connector and an alignment formation;
aligning a mount with the circuit board assembly by mating a protrusion extending from a back side of the mount with the alignment formation provided by the circuit board assembly;
fixing the mount to the circuit board assembly;
moving the power conversion module into alignment with an alignment surface on a front side of the mount, wherein the alignment surface receives a corresponding alignment feature of the power conversion module, to connect the power conversion module with the data connector.

In some embodiments, the method further comprises placing one or more input busbars and one or more output busbars into a corresponding channel of the mount; and slidingly mate clips on the power conversion module with the one or more output busbars and the one or more input busbars by way of moving the power conversion module into alignment with the alignment surface.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

FIG. 1 is a schematic front view of a power conversion module.

FIG. 2 is a schematic front view of multiple power conversion modules.

FIG. 3 is a perspective view of a cabinet with open doors and installed power conversion modules.

FIG. 4 is a perspective front view of a mount.

FIG. 5 is a perspective rear view of the mount.

FIG. 6 is an exploded view showing the mount and related components.

FIG. 7 is a perspective rear view of a mount.

FIG. 8 is an exploded view of an installation with multiple mounts.

FIG. 9 is an exploded view of a backplane assembly.

FIG. 10 is a flowchart of a method for installing a power conversion module in a housing for charging an electric vehicle.

FIG. 11 is a schematic diagram of a charging location.

### DESCRIPTION OF EMBODIMENTS

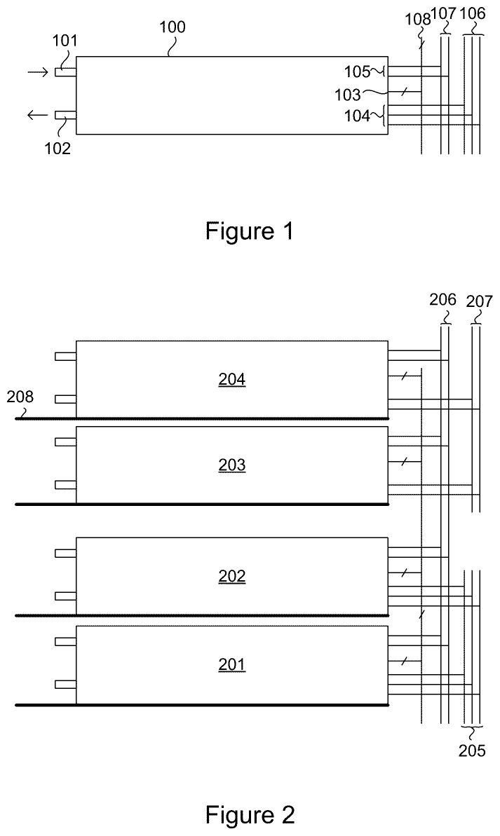

FIG. 1 is a schematic side view of a power conversion module 100. In this example, the power conversion module 100 is liquid cooled and comprises a cooling liquid inlet 101 and a cooling liquid outlet 102 on the left side of the power conversion module 100. Since the cooling liquid may cause shorts and corrosion when in contact with electrical conductors and electrical charge, it is an advantage to locate the cooling liquid inlet 101 and outlet on the side of the power conversion module 100 that is opposite from all of the electrical connectors as described below.

On the right hand side, opposite from the cooling liquid inlet 101 and outlet 102, the power conversion module 100 comprises a data port 103, a power input 104 and a power output 105. In this example, the power input 104 is a three-phase alternating current (AC) input and the output is a two-pole direct current (DC) output. Hence, the power conversion module 100 is a AC/DC rectifier module. In other examples, the power input 104 is a two-pole DC input and the power conversion module 100 is a DC/DC module. In the AC/DC example of FIG. 1, the power input 104 is connected to a three-phase AC busbar 106 and the power output 105 is connected to a two-pole DC busbar 107. It is noted that the singular of busbar is used to denote a two-pole or three-pole busbar with multiple individually isolated conductors for ease of explanation. Alternatively, the busbars can be referred to as AC busbar group 106 (synonymous to AC busbar 106) and two-pole DC busbar group 107 (synonymous to two-pole DC busbar 107). The data connector 103 is connected to a data bus 108. The data connector may have one or more data lines, such as D+ and D− and may be configured to carry standardised bus signals, such as Controller Area Network (CAN) bus signals. The data connector may further carry low voltage power, such as 24V, to power the electronics in the power conversion module 100.

It is noted that the busbars can carry a large amount of power at high voltages. As a result, the physical set-up should provide safety against shorts and other unwanted connections or faults. Therefore, it is undesirable to have cables near the busbars on the right hand side because cables are flexible and can therefore bend and come into contact with the busbars. Therefore, it is desirable that all conductors, including the power conductors as well as data conductors are rigid. As a result, it is not possible to connect power conversion module 100 to data bus 108 using a wired connector, such as a plug on a ribbon cable. Instead, the power conversion module 100 is moved into a mating position with a data connector that is rigidly fastened to the data bus 108. Further, the data bus can be implemented rigidly as metal layers on a printed circuit board (PCB).

FIG. 2 illustrates how the architecture of FIG. 1 can be used to connect multiple power conversion modules in parallel and connect them to the same data bus 108, input busbar 106 and output busbar 107. In that case, the additional power conversion modules are arranged above or below the power conversion module 100 shown in FIG. 1. It is even possible to have one or more AC/DC modules combined with one or more DC/DC modules in the same assembly. As shown in FIG. 2, there are two AD/DC modules 201 and 202 connected to input AC busbar 205. In that hybrid case, the input AC busbar 205 may only run along the AC/DC modules 201 and 202 and then terminate. AC/DC modules 201 and 202 are connected to internal two-pole DC link 206 (also referred to as “DC bus” or “internal DC busbar”), which serves as an input for DC/DC modules 203 and 204. The output of those modules 203, 204 is connected to an output DC busbar 207. The output DC busbar 207 replaces the AC input busbar 205 along the DC/DC modules. When arranged in a cabinet (not shown in FIG. 2), the output DC busbar 207 and the input AC busbar 205 may be installed in the same channel in the cabinet with an air gap or other insulation between them.

Installing the modules into the cabinet will be explained with reference to module 204 as an example, noting that FIG. 2 is a schematic front view of the cabinet. The installer lifts module 204 onto a respective mounting system 208 and then slides the module into a mating position where a data connector mates to provide data communication and power connectors mate with respective busbars to provide a power connection. The mounting system 208 may be a shelf, one or more brackets or other mounting elements on which the power conversion module 100 can slide sidewardly. The installer can then connect the liquid cooling pipes or hoses. It is this sliding movement that presents a difficulty. If tolerances of mechanical guides are not sufficiently low, a misalignment between the power conversion module and the data connector may occur, which can easily damage the data or power connectors or make mating difficult, unreliable or even impossible. It is noted that the connection to the data connector often presents the tightest tolerances in the installation of the power conversion module 100. Therefore, this disclosure focuses on alignment to the data connector, noting that this disclosure can equally be applied to tolerances with respect to other elements, such as power connectors.

One option to ensure low tolerances is to manufacture any mechanical guides by machining the respective parts, such as by using computer numerical control (CNC) machines. However, such a fabrication technique is expensive, wastes material and is slow. It would be an advantage to provide for reliable mating between the power conversion module and the data connector that can be made using high volume, low cost processes, such as using injection moulding. Typically, it is difficult to achieve low tolerances with mass production techniques, such as injection moulding. Therefore, it is difficult to achieve a low tolerance where many different parts are involved. The combination of tolerances arising from a combination or mechanical connection between multiple parts is referred to as “tolerance chain” as each element of that chain contributes to the final tolerance between the power conversion module and the data connector or power connectors. It is desirable to keep that tolerance chain short in order to accumulate fewer tolerances and therefore allow for higher tolerance of each part in the chain.

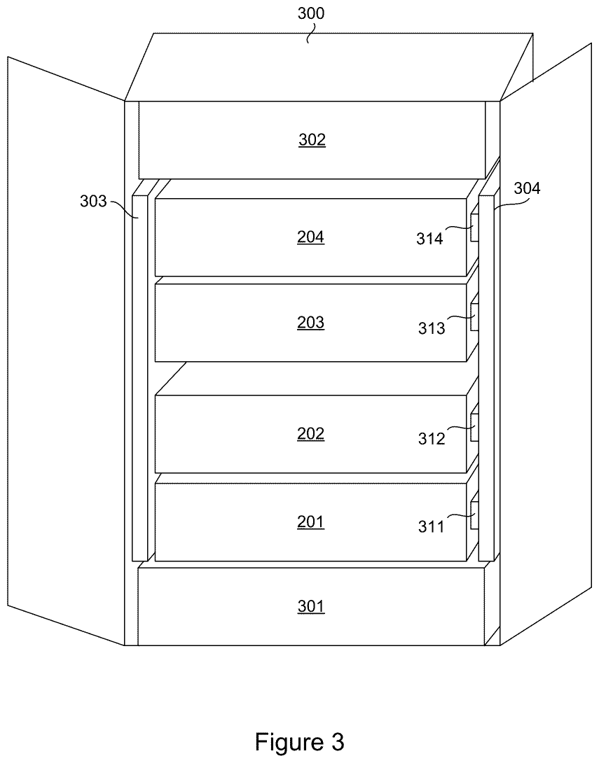

FIG. 3 is a perspective view of the cabinet 300 with open doors. The cabinet has the four modules 201-204 installed therein. There is an input module 301 and an output module 302. It is noted that the cabinet may comprise AC/DC modules as well as DC/DC modules as described above. In other examples, there is a rectification cabinet (unit) with only AC/DC modules and one or more charging cabinets (units) with only DC/DC modules and a DC connection between the first cabinet and the second cabinet. This has the advantage that the installed power for each function of rectification (AC/DC) and EV charging (DC/DC) can be configured more flexibly. In particular, it is possible to “oversubscribe” rectification, which means that the power of the AC/DC modules together is less than the added power of all the DC/DC modules installed in the one or more charging cabinets. This is useful under the assumption that not all chargers are used at their maximum power rating at the same time. This is a realistic assumption in many practical installations. The cabinet 300 further shows a liquid cooling system 303 and an electrical connection (data and power) assembly 304. The electrical connection assembly 304 is also referred to as a backplane assembly and comprises the data bus 108 and the busbars 106/107/205/206/207 shown in FIGS. 1 and 2. Again, the modules 201-204 are supported by shelves (not shown). FIG. 3 also shows mounts 311-314 for the respective power conversion module 201-204. The purpose of the mounts 311-314 is to receive the modules 201-204, respectively, and to align them with respective data connectors in the electrical connection assembly 304 with low tolerance to ensure reliant connection and easy installation.

Returning to the problem of short tolerance chain, this disclosure provides a mount 311-314 for a power conversion module that provides a short tolerance chain and can therefore be mass produced with less material waste and more efficient production.

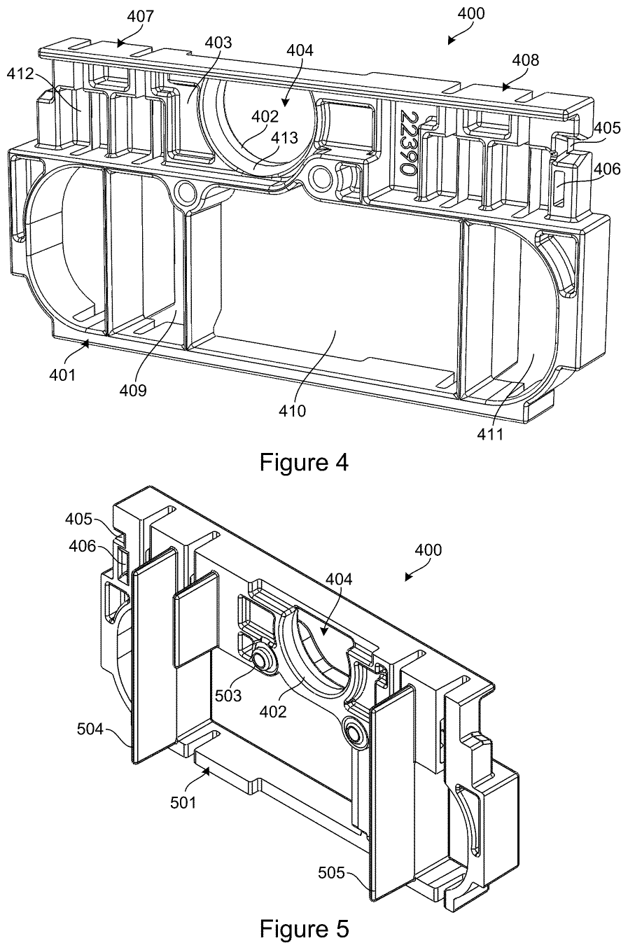

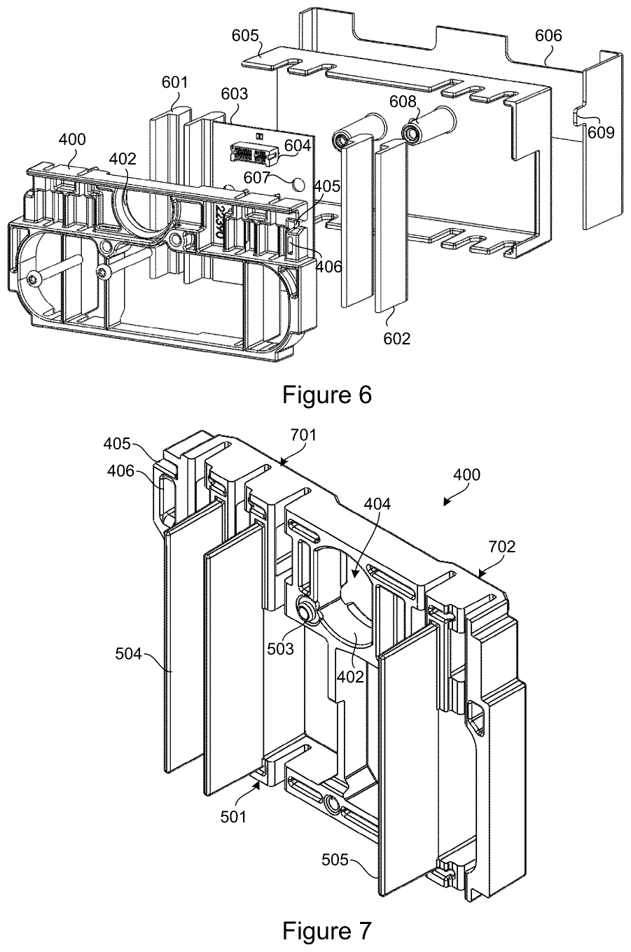

FIG. 4 is a perspective front view of a mount 400 for a power conversion module 100 for charging an electric vehicle according to an embodiment. FIG. 5 is a perspective rear view of mount 400 according to an embodiment. FIG. 6 is an exploded view, according to an embodiment, showing mount 400, input busbar 601, output busbar 602, circuit board assembly 603 comprising data connector 604, a rear component 605 and part of a back plate 606 that provides structural support and is affixed to the side wall of the cabinet. It is noted that the singular of busbar is used to denote a two-pole or three-pole busbar with multiple individually isolated conductors for ease of explanation. Alternatively, these terms could be replaced by positive DC busbar and negative DC busbar for a two-pole DC busbar and first, second, third phase busbar for a three-phase AC busbar.

FIG. 7 is a perspective rear view of another embodiment of mount 400 comprising a three-phase AC input 701 and a two-pole DC output 702, according to an embodiment. The remaining features match with those of the other figures. It is an advantage that the AC/DC mount in FIG. 7 is very similar to the DC/DC mount in the other figures, which means that the same design principles can be applied for both mounts and that the mounts can be easily used in combination. This increases the flexibility of building different power conversion solutions. It is further noted that the AC/DC mount in FIG. 7 is taller that the DC/DC mounts, which is simply because current AC/DC power conversion modules are taller than DC/DC power conversion modules. However, this may change and all modules may be of the same height or DC/DC modules may be taller than AC/DC modules.

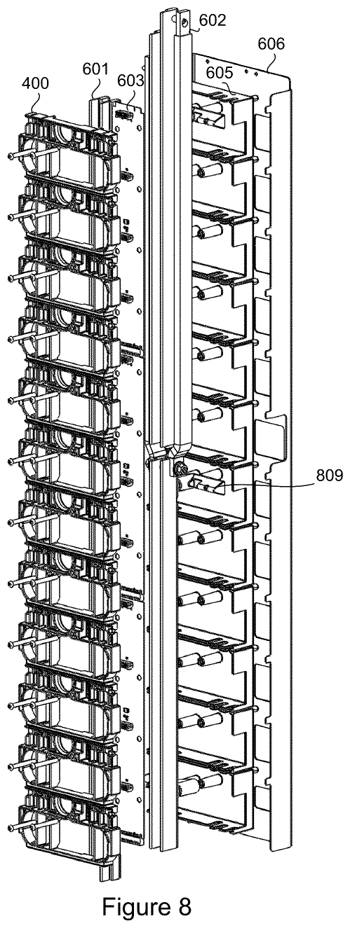

FIG. 8 is an exploded view of an installation, according to an embodiment, with multiple mounts 400, which shows that each power conversion module 100 has a respective mount 400, connector 604 and rear component 605. However, the busbars 601, 602, the circuit board assembly 603 and the back plate 606 extend along the height of multiple or even all power conversion modules 100. As explained above, the busbars may be separated into AC and DC busbars in the same channel if AC/DC rectifiers and DC/DC modules are mixed in the same cabinet.

Mount 400 comprises a front side 401, shown in FIG. 4 to face the power conversion module 100 and a back side 501 shown in FIG. 5 to face circuit board assembly 603 comprising data connector 604. Mount 400 comprises an alignment surface 402 accessible from the front side 401 to receive a corresponding alignment feature of the power conversion module 100 and configured to align the power conversion module 100 with the mount 400 for connection of the power conversion module 100 to the data connector 604. More particularly, power conversion module 100 comprises a protrusion of a matching shape to the alignment surface 402, which can be referred to as a “pin”. A module data connector that complements the data connector 604 of the circuit board assembly 603 is located within the pin, so that when the pin of the power conversion module 100 is pushed into the mount 400, the data connectors mate and form a reliable electrical connection for data communication.

Mount 400 further comprises a protrusion 503 (see FIG. 5) extending from the back side 501 to mate with a corresponding alignment formation 607 (see FIG. 6) provided by the circuit board assembly 603 to align the mount 400 to the circuit board assembly 603. The alignment surface 402 of mount 400 in cooperation with the pin provides alignment with the power conversion module. At the same time, the protrusion 503 provides alignment with the circuit board assembly 603. This way the chain of tolerances is short as it only includes the following alignments:
between the connector in the pin of the power conversion module 100 and the outside surface of the pin (this is typically well controlled by the manufacturer of the power conversion module 100);
between the outside surface of the pin and alignment surface 402;
between the alignment surface 402 and protrusion 503;
between protrusion 503 and alignment formation 607;
between alignment formation 607 and data connector 604 (this is typically well controlled by the PCB manufacturer).

In essence, mount 400 defines a chain of tolerances from the alignment surface 402 of the power conversion module to the data connector 604 of the circuit board assembly 603 via the alignment feature and the alignment surface 402 and via the protrusion 503 and the circuit board assembly 603. In one example, the tolerance of the alignment surface 402 is less than 150 μm and the tolerance of the protrusion 503 is less than 100 μm.

As a result of this very short tolerance chain, accurate alignment between the power conversion module and the circuit board assembly can be achieved. This is particularly useful because it allows the use of manufacturing techniques that do not provide low tolerances throughout. Within the mount, it is only the spatial relationship between the alignment surface 402 and the protrusion 503 that defines the tolerance. As a result, the mount can be mass-produced using more cost efficient manufacturing techniques compared to high precision machining, which is slow and produces a significant amount of material waste. In particular, fewer or no parts of mount 400 need to be machined, which would require high precision machinery and leads to a waste in material and costs.

In one embodiment, protrusion 503 is proximal to the alignment surface 402. This has the additional advantage that the translational tolerance (up/down, left/right) is less impactful on the misalignment between the power conversion module 100 and the data connector 604. That is, the closer together the protrusion 503 is to the alignment surface 402, the smaller the influence of translational misalignment.

In one embodiment, mount 400 is integrally formed with the alignment surface 402 and the protrusion 503, which means these features are made out of one continuous piece of material. For example, mount 400 may be manufactured by injection moulding as a single piece of material. The material may comprise one or more of polyamide, polycarbonate, phenolics or polyesters. In one embodiment, the mount 400 is manufactured of Ultramid B3UGM210. Further, the rear component 605 may be manufactured of the same or different material to the mount 400. Other manufacturing techniques are equally possible, including compression moulding, some other resin moulding processes, etc. In such techniques, it is advantageous to avoid any large blocks of material to aid in uniform cooling and reduce mechanical stress within mount 400. For this reason, mount 400 shows multiple indents in the front side 401 shown in FIG. 4, such as indent 403. Further, in this example, the protrusion 503 is in the same block of material that forms the alignment surface 402 without any indents between them. This provides for a minimum distance between the alignment surface 402 and the protrusion 503.

Alignment formation 607 can take a number of different forms, such as a receptacle or cup or other component affixed to the circuit board. However, to keep the chain of tolerances short, it is advantageous that the circuit board assembly 603 comprises a printed circuit board and the alignment formation 607 is an aperture through the printed circuit board. In other words, the circuit board assembly 603 comprises a through hole to receive protrusion 503. The through hole can be manufactured to low tolerance by existing circuit board manufacturing techniques.

In a further embodiment, protrusion 503 is a boss around a screw hole as shown in FIG. 5. This way, the screw hole can receive a screw that clamps the mount 500 against the circuit board assembly 603. For example, the back plate 606 may comprise threads and may be made of metal, such as steel or aluminium, to provide a durable thread for the screw that clamps the mount 400 to circuit board assembly 603 through posts 608 on rear component 605.

It is noted that the figures show a second screw hole and second post to receive a second screw. However, in those examples, the second screw is only used to provide additional clamping force but is not used for alignment. Rotational alignment between the circuit board assembly 603 and the mount 400 is provided by the stacking of mounts (and extension and duplication of circuit board features) vertically, with successive protrusions 503 in successive mounts 400 and alignment formations 607 acting as pin-pin joints, rotationally constraining these to each other.

In further embodiments, and as shown in the figures, alignment surface 402 is proximal to the data connector 604. Again, this ensures that translational tolerances affect the overall misalignment as little as possible. More particularly, alignment surface 402 may be inside of an opening 404 through the mount. The opening 404 is in a direction of movement of the power conversion module 100 when mating the power conversion module 100 with the data connector 604. This means the opening 404 is substantially horizontal in a left-right direction when looking into the cabinet, so that the pin of the power conversion module 100 can slide into the opening 404 to thereby mate the data connector 604 to the power conversion module 100. In that case, it is advantageous to locate data connector 604 of circuit board assembly 603 within the opening 404 as shown in the figures. The opening may have any shape and it may be advantageous that the opening comprises one or more circular arcs for rotational freedom and one or more straight sections for blocking rotational movements. In one example, the opening 404 is oblong as shown in FIG. 7. The oblong shape may comprise round or circular ends at the shorter side, such as the top and bottom, and straight vertical edges at the longer side, such as the vertical sides. In other examples, such as in FIGS. 4, 5 and 6, the opening 404 comprises a circle arc with a horizontal chord at the top of the opening 404 that cuts away the top segment of the circle.

In some embodiments, the alignment surface 402 is chamfered inwardly from the front side 401 to guide the alignment feature of the power conversion module 100 into a mating position with the alignment surface 402. FIG. 4 shows a chamfer at 413, which essentially forms a ramp for the alignment feature of the power conversion module 100. As a result, when the power conversion module 100 is pushed into the mount 400, the ramp lifts the right side of the power conversion module 100 up by 1-3 mm, for example. As a result, the mounting system 208 can have a relatively high tolerance and within this tolerance the alignment of the power conversion module 100 with the data connector 604 is decoupled from the tolerance in the mounting system 208. Therefore, the mounting system 208 can be manufactured and installed with lower requirements on tolerances, which again simplifies manufacture and installation. The chamfer 413 also guides the alignment feature into mount 400 so that the installer does not need to manually align the power conversion module 100 accurately, which is also referred to as “self-alignment”. The disclosure structure of mount 400 also provides for an uncomplicated installation of the mounts 400, busbars 602, 903, 904, 905, the circuit board assembly 603 and the rear components 605 to assembly the backplane assembly. For a typical installation, this reduces the complexity of installation and reduces the installation time from 20 minutes to less than 5 minutes. The proposed mount also reduces the number of screws to 18 for only rectifier modules and 24 for only DC/DC modules, noting that this is specific to the number of modules as each module has only 2 screws to fasten.

In one embodiment, mount 400 further comprises a slot 405. Slot 405 is located distal from the alignment surface 402 and is configured to receive a corresponding foot of the power conversion module 100. The foot has a shape that corresponds to the shape of slot 405. That is, as the power conversion module 100 slides into mount 400, the foot of the power conversion module 100 slides into slot 405. This foot-to-slot engagement provides rotational alignment to the power conversion module 100. As described above, the engagement of protrusion 503 with engagement formation 607 translationally and rotationally constrains the circuit board assembly 603 and by extension the data connector 604 to the mount 400. The engagement between slot 405 and the foot of the module thereby removes the rotational degree of freedom between the module 100 and the connector 604. It is an advantage that slot 405 is located distal from the alignment surface 402 because the rotational misalignment with the data connector 604 caused by a tolerance in the slot 405 declines with an increase distance between the alignment surface 402 and slot 405. In other words, the further away the slot 405 is from the alignment surface 402, the small the influence of the slot tolerance to the alignment with the data connector 604.

In a further embodiment, mount 400 comprises a load transfer feature 406 to transfer mechanical load from the power conversion module 100 to a back plate 606. In the example shown in the figures, the load transfer feature 406 is a slot that receives a lug 609 extending from the back plate. This way, the back plate 606 can be made of sheet metal with the lug being integrally formed or stamped out of the sheet metal, which again is low cost and lends itself mass manufacture. Advantageously, the load transfer feature 406 is located directly below the slot 405 in mount 400 so that the downward force of the power conversion module 100 acts directly onto the lug 609 applying only compression force onto a small part of the material of mount 400, which reduces distortion of the mount 400 due to the weight of the power conversion module 100, reducing the load carrying requirements of the mount 400.

As foreshadowed above, mount 400 comprises an input channel 407 for housing a vertical input busbar 601 and an output channel 408 for housing a vertical output busbar 602. Input channel 407 and output channel 408 each may have two grooves for a two-pole DC busbar or three grooves for a three-phase AC busbar. It is further noted that the labels “input” and “output” are arbitrarily applied to the left and the right side noting that those sides can be swapped for different applications. However, it is advantageous that the output side of the AC/DC modules is the same as the input side of the DC/DC modules so that both modules can be combined easily without crossing over any busbars. Further, mount 400 comprises fins 504/505 to separate the busbars from each other. This may be a legal requirement and provides further isolation between the busbars that may themselves be blank metal and therefore have no isolation but carry high voltages.

To that end, the mount may comprise openings, such as opening 412 over the input channel 407 and the output channel 408 to receive clips of the power conversion module 100. The clips are configured to slide over the blank metal bus bars and engage with the input busbar and the output busbar, respectively. This provides the electrical power connection between the busbars and the power conversion module 100. It is noted that the disclosed mount can accommodate for extruded busbar profiles, which are easier to manufacture than laser cut/tapered busbars, which is another advantage of the disclosed mounts.

Mount 400 may further comprise openings 409/410/411 to provide for airflow into the power conversion module 100 for additional cooling. This circulating airflow may be generated by fans within the power conversion module 100 or external.

As mentioned above with reference to FIG. 6, there is a rear component 605 to clamp the circuit board assembly 603, the input busbar 601 and the output busbar 602 to the back side 501 of mount 400. To that end, rear component 605 comprises a screw post 608 for receiving a screw fed through the protrusion 503 of the mount 400 and the hole 607 in the circuit board assembly 603. The rear component 605 comprises slots in the side walls to receive the busbars 601, 602 and may also be manufactured in the same way as mount 400, such as using a injection moulded plastic, for example. Rear component 605 may also act as an airflow duct, routing cooling air to openings such as 409/410/411

Referring to FIG. 8, it is noted that the circuit board assembly 603 may comprise a printed circuit board that extends over multiple power conversion modules, such as four power conversion modules as shown in FIG. 8, resulting in three individual printed circuit boards. The individual printed circuit boards are electrically connected by circuit board connectors. The number and length of the printed circuit boards is not particularly relevant and can be changed based on manufacturing requirements. This also improves the design over alternatives that require an entire printed circuit board that spans across all modules.

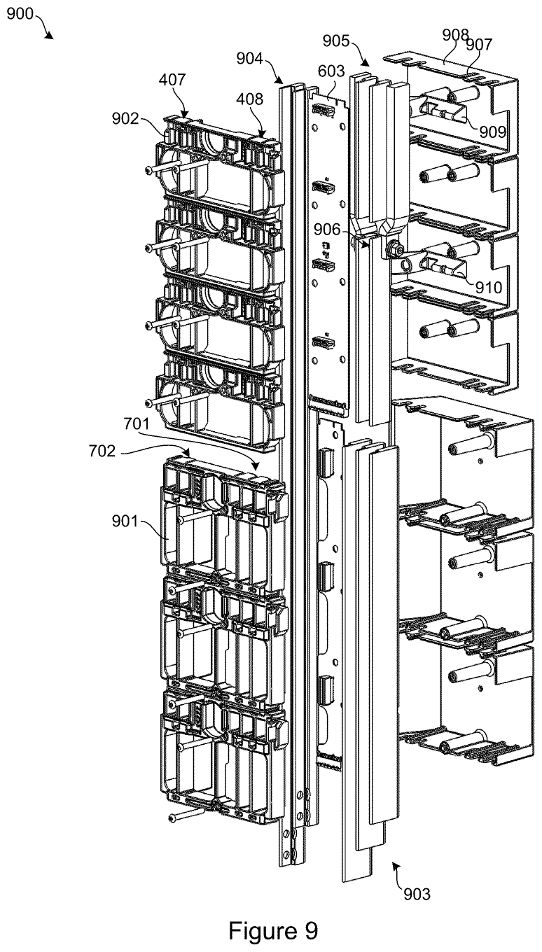

FIG. 9 is an exploded view of a backplane assembly 900 for a housing for multiple power conversion modules (not shown). This is the example mentioned above where AC/DC modules and DC/DC modules are installed into the same cabinet. Backplane assembly 900 comprises one or more first mounts 901 as described with reference to FIG. 7. That is, the first mounts 901 are configured to mount respective AC to DC rectifiers located at the bottom of the backplane assembly 900.

The backplane assembly 900 further comprises one or more second mounts 902 as described with reference to FIGS. 4, 5 and 6. The second mounts 902 are configured to mount respective DC to DC converters located at the top of the backplane assembly 900. An AC busbar 903 connects the rectifiers to an input AC power source. The AC busbar 903 runs through the input channel 701 of the first mounts 901.

The backplane assembly 900 further comprises a first DC busbar 904 connecting the output of the rectifiers to the input of the converters. Accordingly, the first DC busbar 904 runs through the output channel 702 of the first mounts 901 and through the input channel 407 of the second mounts 902.

The backplane assembly further comprises a second DC busbar 905 connecting the output of the converters to an output assembly (see 302 in FIG. 3) and running through the output channel of 408 of the second mounts 902. As can be seen from FIG. 9, the input channel 701 of the first mounts 901 is vertically aligned with and insulated from the output channel 408 of the second mounts 902. This enables the sharing of the vertical channel for AC input and DC output.

The output assembly may comprise a charging cable connected to the output DC busbar 905. The output assembly may also comprise two charging cables. In that case, the output DC busbar 905 is split into two vertical busbars and there is a break out of the bottom DC busbar as indicated in 906. As a result, the bottom half of the DC/DC modules are connected in parallel and their DC output is bypassed to the first charging cable. Similarly, the top half of the DC/DC modules are connected in parallel and their DC output is connected to the second charging cable. As a result, there are four poles shown for second DC busbar 905 in FIG. 9. It is noted that the inner bypass DC pole is received by an additional slot 907 in the rear components 908. The outer bypass DC pole can be located outside the rear component 908.

FIGS. 8 and 9 further show stops 809/909/910 that slide over posts 608 and provide for vertical support of the busbar poles during installation. To that end, the busbar poles may have corresponding notches that rest on the stops 809/909/910 during installation. Once the mounts are installed, the screws clamp the busbars between the rear side of the mount and the rear component and hold the busbars in place. Therefore, the stops are particularly useful during installation while there is no other vertical support for the busbars. However, it is noted that the stops also support the busbars after installation to not only rely on the clamping to keep the busbars in place, which would place a greater burden on the rigidity of the mount.

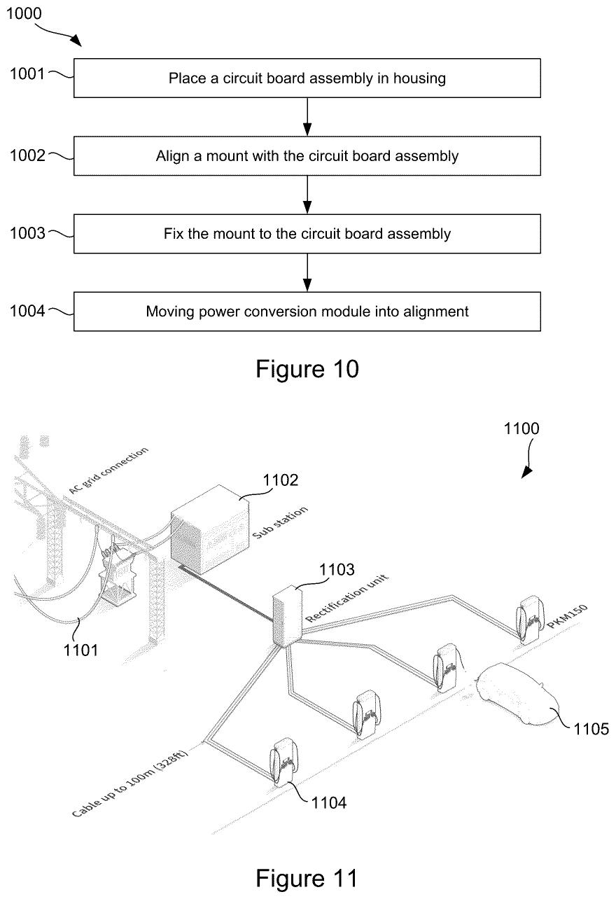

FIG. 10 is a flowchart of a method 1000 for installing a power conversion module 100 in a housing for charging an electric vehicle. The method comprises placing 1001 circuit board assembly 603 in the housing. As described above, circuit board assembly 603 comprises data connector 604 and an alignment formation 607. The method 1000 may further comprise placing one or more input busbars 601 and one or more output busbars 602 into a corresponding channel of the mount 400. The method 1000 further comprises aligning 1002 mount 400 with the circuit board assembly 603 by mating protrusion 503 extending from the back side 501 of the mount 400 with the alignment formation 607 provided by the circuit board assembly 603. Then, the method 1000 proceeds by fixing 1003 the mount 400 to the circuit board assembly 603, such as by feeding a screw through the screw hole and tightening the screw. The screw may interface a thread in the back plate 606 for solid fixation. At this stage, the completed backplane assembly can be mounted into the cabinet. Finally, the method comprises moving 1004 the power conversion module 100 into alignment with an alignment surface 402 on a front side 401 of the mount. During this movement, the alignment surface 402 receives the corresponding alignment feature of the power conversion module 100, so that the power conversion module connects with the data connector 604. Further, this movement causes clips on the power conversion module to slide over the busbars to mate with the one or more output busbars and the one or more input busbars by way of moving the power conversion module into alignment with the alignment surface.

It is noted that various different configurations can be realised using the mount disclosed herein. For example, the voltage of data communication may be 24V, 12V, 6V or any other low voltage. The DC busbars may carry a voltage of 950V or any other high voltage, noting that a higher voltage leads to lower current at equal power, reducing the required cross-sectional area of the busbar poles. The AC input may be three-phase mains voltage of 400V, which again may be different for different countries or applications.

FIG. 11 is a schematic diagram of an EV charging location 1100. The charging location comprises an AC grid connection 1101 and an optional sub-station 1102 to transform a high AC voltage to a low AC voltage. The charging location 1100 further comprises a rectification unit 1103 and one or more charging stations 1104. Each charging station has one or more charging cables to connect an EV 1105 to supply electric power to charge the battery of the EV 1105. In this example, the rectification is separate from the DC/DC conversion. That is, the rectification unit 1103 comprises only AC/DC rectifiers as the installed power conversion modules and provides DC power to the charging stations 1104. This DC power is typically provided at a higher voltage than mains voltage, which means cables can be thinner and therefore lighter and cheaper than for distributing AC mains power to the charging stations individually. The charging stations 1104 include only DC/DC power conversion modules to control the amount of DC power that is delivered to EV 1105. Each charging station 1104 further provides galvanic isolation of each EV 1105 from the AC grid 1101 and from any other EV connected at the same charging location 1100. To that end, in some embodiments, every DC/DC module comprises a galvanic isolation, such as a transformer. The charging stations may provide a range of power up to 150 kW or up to 400 kW. Again, it is possible to install four 400 kW charging stations with a total of 1,600 kW of charging power and connect them to only 800 kW rectification power. This is a 1:2 oversubscription which is useful under the realistic assumption that not all vehicles charge at maximum power at the same time. Therefore, the rectification unit 1103 is used more efficiently than had it been integrated into each charging station 1104.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A mount for a power conversion module for charging an electric vehicle, the mount comprising:
a front side to face the power conversion module;
a back side to face a circuit board assembly comprising a data connector;
an alignment surface accessible from the front side to receive a corresponding alignment feature of the power conversion module and configured to align the power conversion module with the mount for connection of the power conversion module to the data connector; and
a protrusion extending from the back side to mate with a corresponding alignment formation provided by the circuit board assembly to align the mount to the circuit board assembly.

2. The mount of claim 1, wherein the protrusion is proximal to the alignment surface.

3. The mount of claim 1, wherein the mount is integrally formed with the alignment surface and the protrusion.

4. The mount of claim 1, wherein the alignment surface is proximal to the data connector.

5. The mount of claim 1, wherein the alignment surface is inside of an opening through the mount, the opening being in a direction of movement of the power conversion module when mating the power conversion module with the data connector.

6. The mount of claim 5, wherein the data connector of the circuit board assembly is located within the opening.

7. The mount of claim 5, wherein the alignment surface is chamfered inwardly from the front side to guide the alignment feature into a mating position with the alignment surface.

8. The mount of claim 1, wherein the mount defines a chain of tolerances from the alignment surface of the power conversion module to the data connector of the circuit board assembly via the alignment feature and the alignment surface and via the protrusion and the circuit board assembly.

9. The mount of claim 1, wherein the tolerance of the alignment surface is less than 150 μm and the tolerance of the protrusion is less than 100 μm.

10. The mount of claim 1, wherein the circuit board assembly comprises a printed circuit board and the alignment formation is an aperture through the printed circuit board.

11. The mount of claim 1, wherein the protrusion is a boss around a screw hole to clamp the mount against the circuit board assembly.

12. The mount of claim 1, wherein the mount comprises a slot distal from the alignment surface to receive a corresponding foot of the power conversion module to provide rotational alignment to the power conversion module.

13. The mount of claim 12, wherein the mount comprises a load transfer feature to transfer mechanical load from the power conversion module to a back plate, the load transfer feature being directly below the slot.

14. The mount of claim 1, wherein the mount comprises an input channel for housing a vertical input busbar and an output channel for housing a vertical output busbar.

15. The mount of claim 14, wherein the mount comprises openings over the input channel and the output channel to receive clips of the power conversion module, the clips being configured to slidably engage with the input busbar and the output busbar.

16. The mount of claim 15, wherein the mount comprises a rear component to clamp the circuit board assembly, the input busbar and the output busbar to the back side.

17. The mount of claim 16, wherein the rear component comprises a screw post for receiving a screw fed through the protrusion of the mount and the hole in the circuit board assembly.

18. A backplane assembly for multiple power conversion modules, the backplane assembly comprising:
one or more first mounts according to claim 1, the first mounts being configured to mount respective AC to DC rectifiers located at the bottom of the backplane assembly;
one or more second mounts according to any one of the preceding claims, the second mounts being configured to mount respective DC to DC converters located at the top of the backplane assembly;
an AC busbar connecting the rectifiers to an input AC power source, the AC busbar running through the input channel of the first mounts;
a first DC busbar connecting an output of the rectifiers to an input of the converters, the first DC busbar running through the output channel of the first mounts and through the input channel of the second mounts; and
a second DC busbar connecting an output of the converters to an output assembly comprising a charging cable, the second DC busbar running through the output channel of the second mounts,
wherein the input channel of the first mounts is vertically aligned with and insulated from the output channel of the second mounts.

19. A method for installing a power conversion module in a housing for charging an electric vehicle, the method comprising:
placing a circuit board assembly in the housing, the circuit board assembly comprising a data connector and an alignment formation;
aligning a mount with the circuit board assembly by mating a protrusion extending from a back side of the mount with the alignment formation provided by the circuit board assembly;
fixing the mount to the circuit board assembly; and
moving the power conversion module into alignment with an alignment surface on a front side of the mount, wherein the alignment surface receives a corresponding alignment feature of the power conversion module, to connect the power conversion module with the data connector.

20. The method of claim 19, wherein the method further comprises:
placing one or more input busbars and one or more output busbars into a corresponding channel of the mount; and
slidingly mate clips on the power conversion module with the one or more output busbars and the one or more input busbars by way of moving the power conversion module into alignment with the alignment surface.
